(19) United States
(12) Patent Application Publication
(10) Pub. No.: US 2006/0148398 A1
(43) Pub. Date: Jul. 6, 2006

(54) Air vent and method

(76) Inventors: Mark Ruch, The Woodlands, TX (US); Arthur K. Farnsworth, Houston, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/016,951

(22) Filed: Dec. 20, 2004

(51) Int. Cl. H05K 5/00

(52) U.S. Cl. 454/184

(57) ABSTRACT

Various embodiments of an air vent and method for assembling an air vent are provided. In one embodiment an air vent includes a wall comprising a first wall segment which lies along a first plane and a second wall segment which lies along a second plane where the first plane is distinct from the second plane. The air vent also includes at least one opening disposed between the first segment and the second segment of the wall.

### BACKGROUND

Conventional electronic devices, such as, for example, computers and servers, contain heat-generating components that need to be cooled to avoid damage. For example, a typical computer system includes a central processing unit (CPU) that can fail to operate if it reaches above a particular temperature. Such heat sensitive components are typically cooled by providing a flow path for air through air vents along the housing of the electronic device such that the flow contacts the electronic components. For example, cooling air can be drawn through one air vent positioned along one surface of the housing, and across the heat generating components inside the housing to absorb heat energy, before it is exhausted through another air vent positioned along another surface of the housing.

Cooling internal components of electronic devices can be a design challenge, however, because in many cases there is limited space for positioning air vents along the housing of the electronic device due to the presence of functional features, for example, input-output devices, such as CD-Rom or tape drives located near the surface of the housing. In addition, the amount of air flow which can pass through an air vent can be limited by the size of the air vent openings needed to satisfy electromagnetic shielding requirements and safety requirements of the electronic device. Furthermore, as heat transfer requirements of electronic devices have increased, there is a greater need for increased air flow of cool air through the housing.

### BRIEF DESCRIPTION OF THE SEVERAL VIEWS OF THE DRAWINGS

Example embodiments of the present invention can be understood with reference to the following drawings. The components in the drawings are not necessarily to scale. Also, in the drawings, like reference numerals designate corresponding parts throughout the several views.

FIG. 1 is an exploded perspective view of a computer having an air vent, according to an embodiment of the invention;

FIG. 2 is a cutaway perspective illustration of the computer shown in FIG. 1 showing the air vent, according to an embodiment of the invention;

FIG. 3 is an elevational view of the air vent shown in FIG. 2, according to an embodiment of the invention;

FIG. 4 is a cross-sectional view of the air vent of FIG. 3 shown along lines 4-4, according to an embodiment of the invention;

FIG. 5 is a cross-sectional view of an air vent that is planar according to an embodiment of the invention;

FIG. 6 is a cross-sectional view of an air vent having a corrugated vent wall according to an embodiment of the invention; and

FIG. 7 is a cross-sectional view of another air vent having a corrugated vent wall according to an embodiment of the invention.

### DETAILED DESCRIPTION

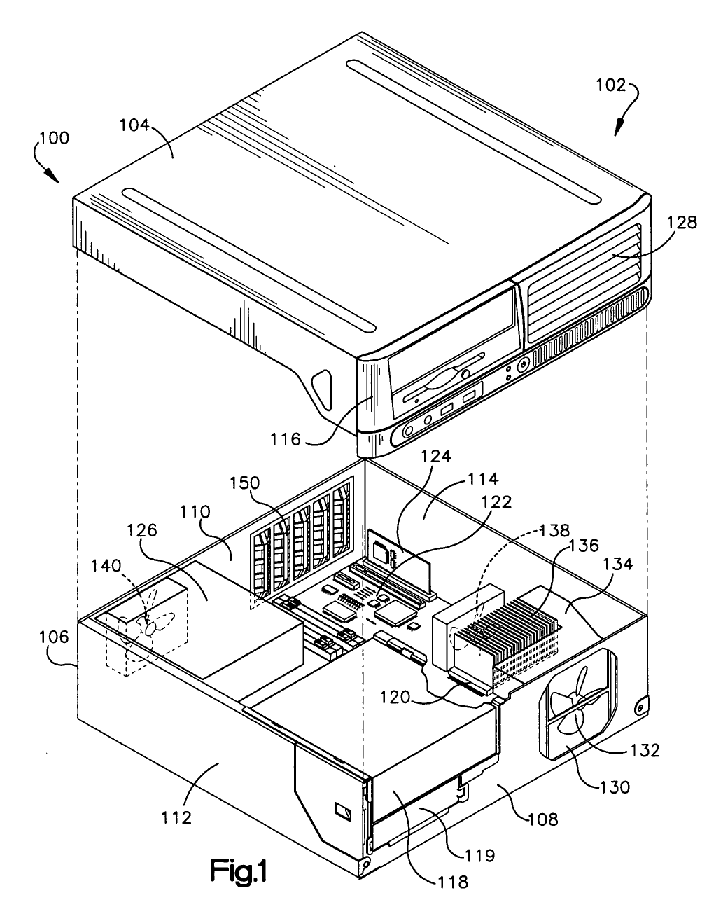

FIG. 1 is a schematic illustration showing an exploded perspective view of an electronic device 100 having a housing 102. The electronic device can be, for example, a computer, a server or one of several electronic devices containing heat-generating and heat-sensitive components.

Housing 102 has a top portion 104 and bottom portion 106 which has front sidewall 108, rear sidewall 110, and opposing left and right sidewalls 112, 114, respectively. Top portion 104 has a bezel 116 which provides user access to input/output devices such as a CD-ROM drive 118 and floppy drive 119 inside the housing 102. Electronic device 100 includes many heat generating components, such as, for example, central processing unit (CPU) 120 which connects to a motherboard (not shown), printed circuit board 122, option card 124, and power supply 126 which supplies electrical power to components of the computer.

Directed airflow is drawn into the housing 102 through louvers 128 of bezel 116 and through opening 130 of housing 102 by suction created by a system fan 132. As shown in FIG. 1 the system fan 132 is oriented such that pressurized stream of air produced by the fan is directed toward the CPU 120. The air then flows through plenum duct 134 and across heat sink 136. During operation the fan draws air from the surrounding ambient air into the interior of the housing through opening 130 and plenum duct 134. Plenum duct 134 can prevent recirculation of air within the housing 102 and can also serve to reduce the amount of acoustic noise produced by the fans, for example system fan 132.

The air can be further propelled by a heat sink fan 138 (shown in phantom) which can be mounted along a wall of a plenum duct 134, and also by a power supply fan 140 (shown in phantom) mounted along rear sidewall 110 or the rear panel of the power supply 126. Heat sink fan 138 and power supply fan 132 direct airflow across the printed circuit board 122 and out of the housing 1002 through air vent 150 disposed along rear sidewall 110. An alternative or an additional air vent (not shown) can also be located within the rear sidewall 110 adjacent the power supply fan 140. Alternatively, the rear panel of the power supply 126 can form a portion of the rear sidewall 110 of the housing 102 such that the rear panel of the power supply 126 forms a portion of the rear sidewall 110 of the housing 102 of the electronic device 100. As shown in FIG. 1 the opening 130 for air intake is located opposite the air vent 150, however, opening 130 and air vent 150 can be aligned differently, for example, diagonally across from one another. As noted above additional or alternative air vents may be located at various locations of the electronic device, for example, on the top portion 104 of housing 102, left and right side walls 112, 114, or wherever space permits so that cool air can be circulated through the housing.

The housing 102 may be made of various materials, for example, metal and polymer such as thermoplastics. The housing 102 may be of various shapes such as is appropriate for containing component of the electric device 100. For example, the external shape of the electronic device may be rectangular, square, or another appropriate shape.

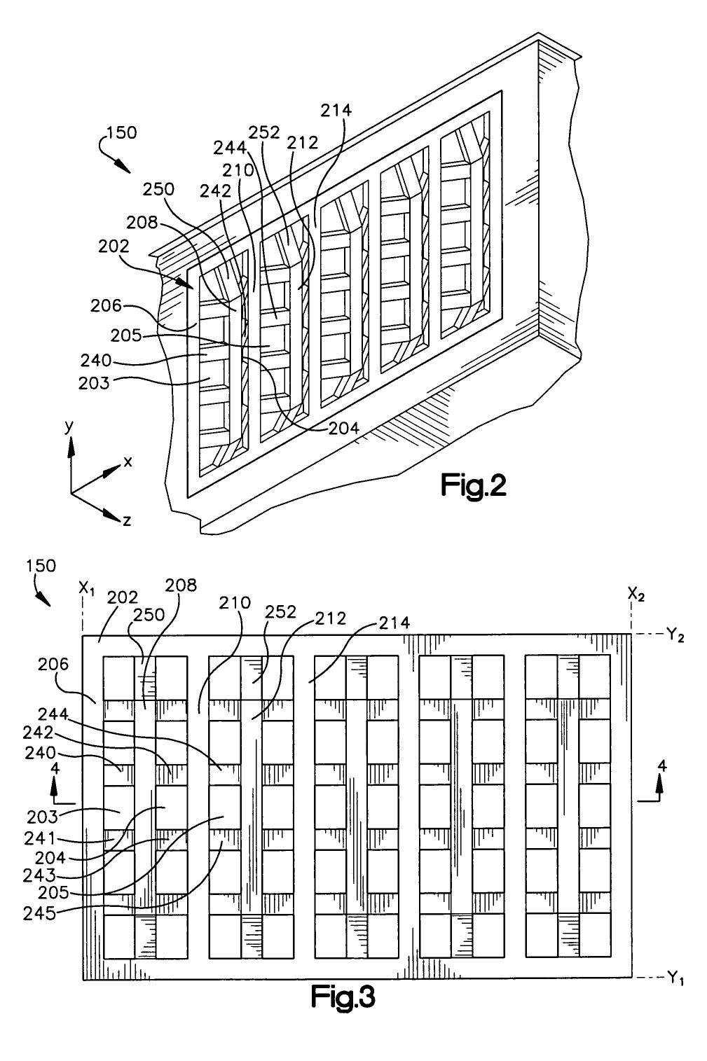

FIG. 2 is a perspective view of cutaway portion of the electronic device 100 of FIG. 1 showing the air vent 150 according to an embodiment of the invention. The air vent 150 includes a wall 202 having at least one opening, for example, openings 203, 204, 205, through which a desired flow rate of air can flow into the interior portion of the housing 102 to dissipate heat to prevent damage of the heat-sensitive components, such as for example, CPU 120 (FIG. 1) described above.

The amount of air flowing through the air vent 150 may be controlled by the size and number of the openings, for example openings 203, 204, 205 of the air vent 150. Considerations for sizing the openings include, but are not limited to, air flow requirements, electromotive (EM) requirements, safety requirements, and width and the thickness of the wall segments, for example wall segments 206, 208, 210, 212, 214, which define the openings. More specifically, the size of each opening 203, 204, 205 can be limited by safety regulation standards and issued as set forth by Underwriters Laboratories (UL) for example. In addition, the openings of air vent 150 can also be sized to provide effective electromagnetic (EM) shielding. Electromagnetic energy or “noise” which originates from different components in the electronic device 100 can interfere with the operation of electrical equipment outside the electronic device 100. The housing 102 provides a shield to contain the noise. Therefore, the air vent of FIG. 2 can effectively ventilate the air to provide heat transfer via a plurality of openings that are sized to meet safety requirements and also EM shielding requirements within the regulatory frequency limit.

In an embodiment of the air vent 150 shown in FIG. 2 the surface of the wall 202, is corrugated and includes a plurality of wall segments that form vent grooves, for example wall segments 206, 210, and 214, and a plurality of wall segments that form vent ridges, for example wall segments 208, 212. As shown, the plurality of vent grooves, for example wall segments 206, 210, 214, are substantially parallel to the plurality of vent ridges, for example, wall segments 208, 212, however, the plurality of vent grooves and the plurality of vent ridges do not have to be parallel with respect to one another. The slanted supports, for example wall segments 240, 241, 242, 243, 244, 245, 250 and 252, are disposed between the plurality of vent grooves and vent ridges, and are positioned at an angle relative to each of the plurality of vent grooves and vent ridges as will be further described. Air vent 150 includes at least one opening between each of the wall segments that form a vent groove and a vent ridge. For example opening 203 is defined by a vent groove and a vent ridge, vertical wall segments 206, 208, respectively, and a pair of horizontal slanted supports, wall segments 240, 241. Openings 204, 205, are each defined by a vent groove and a vent ridge, wall segments 208, 210 and 210, 212, and horizontal slanted supports 242, 243 and 244, 245.

FIG. 3 shows a plan view of the air vent 150 of FIG. 2 having a width that extends along the x-axis from X₁ to X₂ and a height that extends along the y-axis from Y₁ to Y₂. The width and height of vent wall 202 can be sized such that the perimeter of air vent 150 corresponds to the size of an opening of an electronic device, for example an opening along rear sidewall 110 (FIG. 1) of electronic device 100 (FIG. 1). As shown, air vent 150 has fifty openings arranged in a two-dimensional array of ten columns of openings along the horizontal x-axis between X₁ to X₂ and five rows of openings along the vertical y-axis between Y₁ and Y₂. The “open area” of the air vent 150, as employed herein, is the sum of the area of each of the openings, for example openings 203, 204, 205, along the surface of wall 202 which allows air flow through the air vent 150.

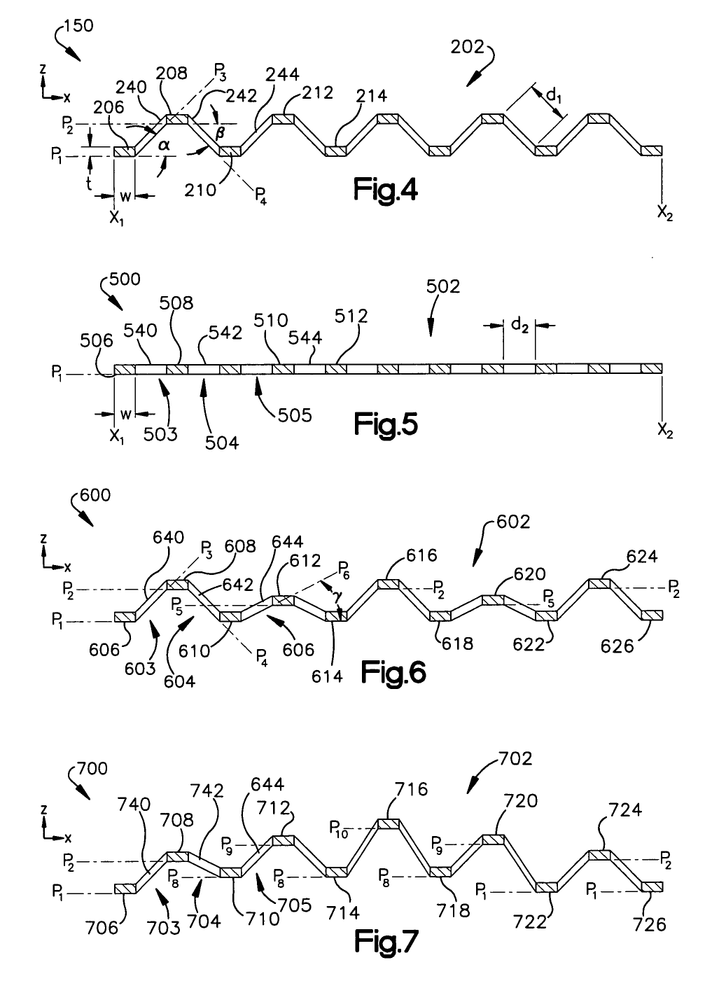

FIG. 4 is a cross-sectional view of air vent 150 FIG. 3 taken along lines 4-4. The cross-section of air vent 150 shows a first wall segment 206 which is a vent groove that lies along a first plane P₁, and a second wall segment 208 which is a vent ridge that lies along a second plane P₂ that is distinct from the first plane P₁. Opening 203 (FIGS. 2 and 3) of vent wall 202 lies along a third plane P₃ that intersects the first plane P₁ and the second plane P₂. Opening 203 is adjacent to a slanted support, wall segment 240, which also lies along plane P₃. Opening 203 and the slanted support defined by wall segment 240 are oriented at an angle, α, relative to wall segment 206, a vent groove, which lies along plane P₁. Angle alpha, α, according to one embodiment can range up to about 90°, in another embodiment can range from about 20° to about 70°, and in yet an alternative embodiment, can range from about 40° to about 50°, and other ranges of angles therebetween.

As shown in FIG. 4, vent wall 202 of air vent 150 can also include a third wall segment 210 that lies along the first plane P₁. Wall segment 210 can be in the same plane as either of the wall segments 206, 208, which lie along planes P₁ and plane P₂, respectively, or the third wall segment 210 can lie along a plane that is different than both the first plane P₁ and the second plane P₂. Opening 204 (FIGS. 2 and 3) of vent wall 202 lies along a fourth plane P₄ that intersects the first plane P₁ and second plane P₂. Opening 204 is adjacent to slanted support wall segment 242, which also lies along plane P₄. Opening 204 and the slanted support defined by wall segment 242 are oriented at an angle beta, β relative to wall segment 208 which lies along plane P₂. Angle beta can range, for example, up to about 90°, in another embodiment can range from about 20° to about 70°, and in an alternative embodiment can range from about 40° to about 50°, and other ranges of angles therebetween.

FIG. 5 shows a cross-sectional view of an air vent 500 which lies substantially along a single plane, P₁, according to another embodiment. Air vent 500 is shown having ten openings, for example openings 503, 504, 505, along the horizontal x-axis between X₁ and X₂. The ten openings can be ten of fifty openings arranged in a two-dimensional array (not shown) where the width of air vent 500 is the same as air vent 150 having a width of ten columns of openings along the x-axis between X₁ to X₂ and a height of five rows of openings along the vertical y-axis between Y₁ and Y₂ (See FIG. 3).

Although air vent 150 (FIGS. 2-4) and air vent 500 (FIG. 5) may have equal perimeters in the X-Y plane (FIG. 3), the open areas of the air vents 150, 500, can differ. Vent surface 202 (FIG. 4) of air vent 150 which is corrugated can have a greater surface area than vent surface 502 (FIG. 5) of air vent 500 and can provide for a larger open area to ventilate air. The distance between the wall segments of air vent 150 (FIG. 4) as represented by distance d₁, is greater than the distance between the wall segments of air vent 500 (FIG. 5) as represented by distance d₂. For example, the size of opening 203 (FIG. 3) of air vent 150 along plane P₃ (FIG. 4), as measured by the distance d₁ between wall segments 206 and 208, is greater than size of opening 503 (FIG. 5) of air vent 500 along plane P₁ as measured by the distance d₂ between wall segments 506 and 508.

The open area of air vent 150 can be compared to the open area of air vent 500 assuming, for example, that the size of the 50 openings of air vent 150 are square openings with sides of 3.5 millimeters (i.e. the width represented by the distance d₁ between wall segments is 3.5 millimeters) and that the angle alpha (FIG. 4) of air vent 150 between planes P₁ and P₃ is 45°. In such case, each of the square openings of air vent 150 has a maximum span opening of less than about 5 millimeters along their respective diagonals (not shown), and the area of each opening, for example opening 203, 204, 205, is 12.25 square millimeters. Thus the open area of air vent 150 is 612.5 sq. mm (50 openings×12.25 sq. mm=612.5 sq. mm). Air vent 500 (FIG. 5) likewise has an array of 50 openings, for example openings 503, 504, 505, each of which has the same height (3.5 millimeters) as the openings of air vent 150, for example openings 203, 204, 205. However, the width of each opening of air vent 500 (i.e. the width represented by the distance d₂ between openings) are smaller than each width of the openings of air vent 150 (i.e. the width represented by the distance d₁). Since d₁ is 3.5 millimeters and the angle alpha is 45°, then according to the well-known Pythagorean Theorem, the width of each of the openings of air vent 500 (FIG. 5) is about 2.7 millimeters. Therefore, the area of each opening, for example opening 503, 504, 505, is 8.65 square millimeters (2.47 mm×3.5 mm) and the open area of air vent 500 is 432.25 sq. mm (50 openings×8.65 sq. mm=432.25 sq. mm). Thus, according to the example dimensions described, the corrugated air vent 150 has an open area that is 41.7% greater (612.5−432.25)/432.25×100) than the open area of the planar air vent 500.

Referring to the example embodiment of air vent 150 shown in FIGS. 3, the physical dimensions of wall segments, for example wall segments 206, 208, and 210, which surround wall openings 203, 204, are approximately equal in size, however uniformity in size is not necessary. The width, w, (FIG. 4) of the wall segments along the x-axis and the thickness, t, (FIG. 4) of the wall segments along the z-axis can be specified by one of ordinary skill in the art in order to provide adequate tensile strength during manufacturing. Minimum boundary distances between each opening 203, 204, 205 may exist to prevent excessive stress and deformation so that the air vent 150 is not sufficiently weakened as to easily damage during manufacturing, installation, or use. The width, w, of each wall segment, for example, wall segment 206, can be based on the relative thickness, t, of wall segment 206 as well as the size of the opening 203. For example, if the thickness, t, of the wall segment 206 along the z-axis is 1 millimeter, then the width of the wall segment 206 along the x-axis can be at least about 1.5 millimeters. The thickness of the wall 202 and the individual wall segments can also depend upon the characteristics of the material used to construct the air vent 150. The relative size of the wall segments and the openings can also be determined by the manufacturing operation employed and the material of use and would be known by those having ordinary skill in the art.

The shape and pattern of the openings can be selected based on the air flow requirements, electromagnetic (EM) shielding requirements, and safety requirements described above. With reference to FIG. 3, for example, the size of each square opening, such as openings 203, 204, 205 measured along a single axis, for example along the y-axis, can be about 10 millimeters or less, for example about 7 millimeters or less, in alternative embodiment, about 5 millimeters or less, in yet an alternative embodiment, from about 3 to about 5 millimeters, and various ranges therebetween. However, it is understood that the size of the openings 203, 204, 205 can be any appropriate dimension given design parameters described herein. The shape of the openings 203, 204, 205 shown in FIG. 3 appear rectangular along the X-Y plane where the openings 203, 204, 204 are square along the third plane P₃ (FIG. 4) that intersects planes P₁ and P₂. Other shapes, besides square, can be used such as, rectangular, round, oval, elliptical, triangle, trapezoid, for example, and other shapes to facilitate air flow.

FIG. 6 shows a cross-sectional view of air vent 600 according to another embodiment of the present invention that can be used in an electronic device, for example electronic device 100 of FIG. 1. The wall 602 of air vent 600 is corrugated and includes a plurality of wall segments 606, 610, 614, 618, 622 and 626 that form grooves and a plurality of wall segments 608, 612, 616, 620 and 624 that form ridges. The plurality of wall segments 606, 610, 614, 618, 622 and 626 that form vent grooves all lie along plane P₁. In this example, some of the wall segments that form vent ridges lie in distinct planes P₂, P₅. For example, wall segments 608, 616, and 624 lie along plane P₂ which is distinct from plane P₁, and some of the wall segments that form vent ridges, for example wall segments 612 and 620, lie along plane P₅ which is distinct from both planes P₁ and P₂. Therefore, only a portion of the wall segments that represent vent ridges are disposed along the same plane. As in the example embodiment of air vent 150 (FIG. 4) the wall segments that form vent grooves are substantially parallel to wall segments that form vent ridges. That is, wall segments in planes P₁, P₂ and P₅ are substantially parallel to one another, however, they may be positioned at alternative angles with respect to one another.

Air vent 600 includes a plurality of openings, for example openings 603, 604, 605 which extend along distinct planes P₃, P₄ and P₆, respectively, and are adjacent to slanted supports which are wall segments 640, 642, and 644, respectively. Because wall segment 612 which is a vent ridge lies along plane P5 which is distinct from planes P1 and P2, opening 605 and the slanted support represented by wall segment 644 extend along plane P6 and are oriented at an angle gamma, γ, relative to plane P₁, which is distinct from angle alpha, α, (FIG. 4). Angle gamma γ can range, for example, up to about 90°, in another embodiment can range from about 20° to about 70°, and in an alternative embodiment, can range from about 40° to about 50°, and other ranges of angles therebetween. The size of the angle gamma can determine the size of an opening, for example the width of opening 605, and therefore the open area of air vent 600.

FIG. 7, in yet another embodiment of the invention, is a cross-sectional view of an air vent 700 that can also be used in an electronic device, for example electronic device 100 of FIG. 1. The plurality of wall segments that form vent grooves, for example wall segments 706, 710, 714, 718, 722, and 726, are disposed in at least two distinct planes, and the plurality of wall segments that form vent ridges, for example wall segments 708, 712, 716, 720, 724 are disposed in at least two distinct planes. The wall segments that form grooves, for example, wall segments 706, 722 and 726 lie in plane P₁ and wall segments 710, 714, and 718 lie in plane P₈ which is distinct from plane P₁. The wall segments that form vent ridges, for example, wall segment 708 and 724 lie in plane P₂, wall segments 712 and 720 lie in plane P₉, and wall segment 716 lies in plane P₁₀ where the planes P₁, P₂, P₈, P₉ and P₁₀ are distinct from one another. The wall segments that form grooves can be substantially parallel to wall segments that form ridges, i.e. wall segments in planes P₁, P₂, P₈, P₉ and P₁₀ are shown as substantially parallel to one another, however, they may be positioned at alternative angles with respect to one another. The openings, for example openings 703, 704, 705, disposed between the wall segments that form vent grooves and vent ridges, can extend along a plane at various angles that range up to about 90° relative to the first plane P₁ as described above with respect to air vents 150 and 600 shown in FIGS. 4, and 6, respectively.

The “percent open area” of each of the air vents of the example embodiments described above, can be determined by the ratio of the “open area” (defined above) along the surface of the vent, for example vent surface 202, to the “overall area” of the vent which includes the open area, times 100 (i.e. open area/overall area×100). The percent open area of the air vents of the various embodiments described above can be at least about 50%, in another embodiment, the percent open area can range from about 50% to about 80%, and in yet an alternative embodiment, the percent open area can range from about 60% to about 70%.

The air vent, for example air vents 150, 500, 600 and 700, can be made from metal or metal coated material, or plastic coated with a conductive material or a flexible polymer. Nonmetallic materials could be used if they are coated or alloyed with a conductive material such as, for example, aluminum, gold, silver, copper, ferrous metals, metal alloys, or any other material suitable for use as a Faraday cage.

If the air vent is made of metal, the openings can be formed by standard punching technique, in which multiple openings can be gang punched, however, other techniques such as drilling can be used. The opening can be punch formed or molded such that it chamfer or bevel that surrounds the opening upon which dust cannot easily adhere. If the air vent is made of plastic then the air vent can be injection molded such that the wall segments that define the openings can extend along three axes without stamping, and the wall segments can be made in different widths and thicknesses depending upon the material selected.

Although the invention is shown and described with respect to certain embodiments, it is obvious that equivalents and modifications will occur to others skilled in the art upon the reading and understanding of the specification. The present invention includes all such equivalents and modifications, and is limited only by the scope of the claims.

What is claimed is:

1. A vent comprising:
a wall comprising a first wall segment disposed along a first plane and a second wall segment disposed along a second plane, the first plane being distinct from the second plane; and
an opening disposed between the first wall segment and the second wall segment.

2. The vent of claim 1, wherein the opening extends along a third plane that intersects the first plane and the second plane, and the first plane is positioned at an angle alpha that ranges up to about 90 degrees relative to the third plane.

3. The vent of claim 2, wherein the angle alpha ranges from about 40 degrees to about 50 degrees.

4. The vent of claim 1, wherein the wall further comprises:
a third wall segment; and
a second opening disposed between the second wall segment and the third wall segment.

5. The vent of claim 4, wherein:
the second opening extends along a fourth plane;
the fourth plane is positioned at an angle beta that ranges up to about 90 degrees relative to the second plane.

6. The vent of claim 4, wherein the third wall segment is disposed along the first plane.

7. The vent of claim 4, wherein the third wall segment is disposed along a fifth plane that is distinct from the first plane and the second plane.

8. The vent of claim 1, wherein the size of the opening, measured along a single axis, is about 5 millimeters or less.

9. The vent of claim 1, wherein:
the opening extends along a third plane that intersects the first plane and the second plane; and
the shape of the opening along the third plane is substantially square.

10. The vent of claim 1, wherein the wall is corrugated, the wall comprising a plurality of vent grooves, a plurality of vent ridges, and at least one opening disposed between each of the plurality of vent grooves and each of the plurality of vent ridges.

11. The vent of claim 10, wherein at least one of the plurality of vent grooves is disposed along the first plane and at least one of the plurality of vent ridges is disposed along the second plane.

12. The vent of claim 10, wherein the percent open area of the vent is at least about 50%.

13. The vent of claim 10, wherein an opening disposed between one of the plurality of vent grooves and one of the plurality of vent ridges is disposed along a third plane that intersects the first plane and the second plane.

14. The vent of claim 13, wherein the first plane is positioned at an angle alpha that is less than about 90 degrees relative to the third plane.

15. The vent of claim 14, wherein the first plane is substantially parallel to the second plane.

16. An electronic device comprising:
a plurality of electronic components disposed within an enclosure; and
a vent comprising:
a wall comprising a first wall segment disposed along a first plane and a second wall segment disposed along a second plane, the first plane being distinct from the second plane; and
an opening disposed between the first wall segment and the second wall segment.

17. The electronic device of claim 16, wherein the opening extends along a third plane that intersects the first plane and the second plane, and the first plane is positioned at an angle alpha that ranges up to about 90 degrees relative to the third plane.

18. The electronic device of claim 17, wherein the wall further comprises:
a third wall segment; and
a second opening disposed between the second wall segment and the third wall segment.

19. The electronic device of claim 18, wherein:
the second opening extends along a fourth plane;
the fourth plane is positioned at an angle beta that ranges up to about 90 degrees relative to the second plane.

20. The electronic device of claim 18, wherein the third wall segment is disposed along the first plane.

21. The electronic device of claim 18, wherein the third wall segment is disposed along a fifth plane that is distinct from the first plane and the second plane.

22. The electronic device of claim 16, wherein the size of the opening, measured along a single axis, is about 5 millimeters or less.

23. The electronic device of claim 16, wherein:
the opening extends along a third plane that intersects the first plane and the second plane; and
the shape of the opening along the third plane is substantially square.

24. The electronic device of claim 16, wherein the wall is corrugated, the wall comprising a plurality of vent grooves, a plurality of vent ridges, and at least one opening disposed between each of the plurality of vent grooves and each of the plurality of vent ridges.

25. The electronic device of claim 24, wherein at least one of the plurality of vent grooves is disposed along the first plane and at least one of the plurality of vent ridges is disposed along the second plane.

26. The electronic device of claim 25, wherein the percent open area of the vent is at least about 50%.

27. A vent in an enclosure comprising:
first wall segment means disposed in a first plane of the vent for providing a plurality of vent grooves; and
second segment means disposed in a second plane of the vent for providing a plurality of vent ridges, the second plane being distinct from the first plane.

28. The vent of claim 27, further comprising means for facilitating the passage of air disposed between the first wall segment means and the second wall segment means.

29. A method for providing a vent in an enclosure, comprising:
forming at least one opening between a first wall segment and a second wall segment of the vent;
disposing the first segment of the vent along a first plane; and
disposing the second segment of the vent along a second plane, the second plane being distinct from the first plane.
